(19) United States
(12) Patent Application Publication
(10) Pub. No.: US 2026/0013175 A1
(43) Pub. Date: Jan. 8, 2026

(54) SEMICONDUCTOR DEVICE AND MANUFACTURING METHOD THEREOF, AND ELECTRONIC MACHINE

(71) Applicants: Sanken Electric Co., Ltd., Saitama-ken (JP); SANKEN ELECTRIC KOREA CO.,LTD., Seoul (KR)

(72) Inventors: Toshihiro Hachiyanagi, Saitama-ken (JP); Akihiko Hirata, Saitama-ken (JP); Yuki Tanaka, Saitama-ken (JP); Soo Lim, Seoul (KR); JinWoo Han, Seoul (KR)

(73) Assignees: Sanken Electric Co., Ltd., Saitama-ken (JP); SANKEN ELECTRIC KOREA CO.,LTD., Seoul (KR)

(21) Appl. No.: 19/245,415

(22) Filed: Jun. 23, 2025

(30) Foreign Application Priority Data
Jul. 2, 2024 (JP) 2024-106939
Apr. 21, 2025 (JP) 2025-069811

(51) Int. Cl. H10D 30/66; H10D 30/01; H10D 64/00

(52) U.S. Cl. CPC H10D 30/668; H10D 30/0291; H10D 64/117

(57) ABSTRACT

Provided is a semiconductor device, which includes: a drift region of a first conductivity type, a base region of a second conductivity type on the drift region, a source region of a first conductivity type on the base region, a gate electrode disposed on the base region via an insulating film, an auxiliary trench provided on the base region, and a polysilicon electrode of a first conductivity type, electrically connected to the base region and the source region, and provided in the auxiliary trench.

### CROSS-REFERENCE TO RELATED APPLICATION

This application claims the priority benefit of Japan application serial no. 2024-106939, filed on Jul. 2, 2024 and Japan application serial no. 2025-069811, filed on Apr. 21, 2025. The entirety of each of the above-mentioned patent applications is hereby incorporated by reference herein and made a part of this specification.

### BACKGROUND

### Technical Field

Embodiments of the disclosure relate to a semiconductor device and a manufacturing method thereof, and an electronic machine.

### Description of Related Art

Conventionally, a semiconductor device of a source trench structure, in which source trenches are provided so as to sandwich a gate trench, has been proposed.

### Related Art Literature(s)

### PATENT LITERATURE

[Patent Literature 1] Japanese Patent No. 7161043.

In the semiconductor device of the source trench structure of Patent Literature 1, both the n-type source region and the p-type body region are connected to an auxiliary electrode made of a p-type polysilicon electrode. The low-resistance contact (ohmic contact) between the p-type polysilicon electrode and the source region is not sufficient, and the on-resistance of the transistor increases. Further, the p-type body region also serves as a region where a channel is formed, and the impurity concentration of the p-type base region can not be made very high. During the off-state of the semiconductor device, in the case of an avalanche breakdown, as holes move through the body region having a relatively low impurity concentration, a potential drop occurs directly below the source region, and due to this potential drop, a parasitic transistor operation occurs, and there is a problem that secondary breakdown occurs and the chip is destroyed.

Conventional semiconductor devices had the concern that the on-resistance increases, and also that, during the off-state, an avalanche breakdown occurs and the chip is destroyed.

The disclosure provides a semiconductor device that suppresses an increase in on-resistance and suppresses avalanche breakdown.

### SUMMARY

A semiconductor device according to an embodiment includes: a drift region of a first conductivity type; a base region of a second conductivity type on the drift region; a source region of a first conductivity type on the base region; a gate electrode disposed on the base region via an insulating film; an auxiliary trench provided on the base region; and a first conductivity type polysilicon electrode, electrically connected to the second conductivity type base region and the first conductivity type source region, and provided in the auxiliary trench.

### BRIEF DESCRIPTION OF THE DRAWINGS

FIG. 1 is a top view of the overall structure of the semiconductor device according to the first embodiment.

FIG. 2 is a cross-sectional view taken along line I-I of FIG. 1.

FIG. 3 is a top view of the overall structure of the semiconductor device according to the second embodiment.

FIG. 4 is a cross-sectional view taken along line II-II of FIG. 3.

FIG. 5 is a cross-sectional view of the semiconductor device according to the third embodiment.

FIG. 6 is a cross-sectional view of the semiconductor device according to the fourth embodiment.

### DESCRIPTION OF THE EMBODIMENTS

According to the disclosure, a semiconductor device that suppresses an increase in on-resistance and suppresses avalanche breakdown may be provided.

Next, embodiments of the disclosure will be described with reference to the drawings. In the following description of the drawings, identical or similar portions are denoted by identical or similar reference numerals. However, it should be noted that the drawings are schematic, and the relationship between thickness and planar dimensions, the ratio of the length of each part, and the like, differ from actual ones. Thus, specific dimensions should be determined by considering the following description. Furthermore, it is a matter of course that the drawings themselves also include portions where mutual dimensional relationships and ratios differ.

Furthermore, the embodiments described below illustrate a device for embodying the technical idea of the disclosure, and the technical idea of the disclosure does not specify the shape, structure, arrangement, and the like of constituent components to those described below. The embodiments of the disclosure may be variously modified within the scope of the claims. It should be noted that, in the disclosure, terms specifying up and down, such as “upper”, “on”, “below”, and “lower,” are used for convenience of description, and even in the case of being provided on a side surface, if they are substantially the same as the constituent elements of the disclosure, they fall within the scope of rights of the disclosure. Further, the term “on” not only includes a case of being formed in contact with an object, but also includes a case of being formed via another layer.

In the following description, the direction of the semiconductor device is defined by the XYZ axes. In a cross-sectional view, the left-right direction is the X-axis direction, the direction perpendicular to the plane of the paper is the Y-axis direction, and the direction perpendicular to the XY plane is the Z-axis direction. It is noted that these directions are an example. Depending on the arrangement of the pattern, they may be appropriately changed. Further, in the following description, a gate structure of a trench gate type is shown, but it may also be applied to a gate structure of a planar type. Further, although a MOSFET is given as an example, it may also be applied to other known MOS structures such as an IGBT (insulated gate bipolar transistor). Instead of an IGBT, it may be an element of another insulated gate structure such as an IEGT (injection enhanced gate transistor). Further, it may be a super junction MOSFET or a complementary metal oxide semiconductor field effect transistor (CMOSFET).

### First Embodiment: Structure Example 1

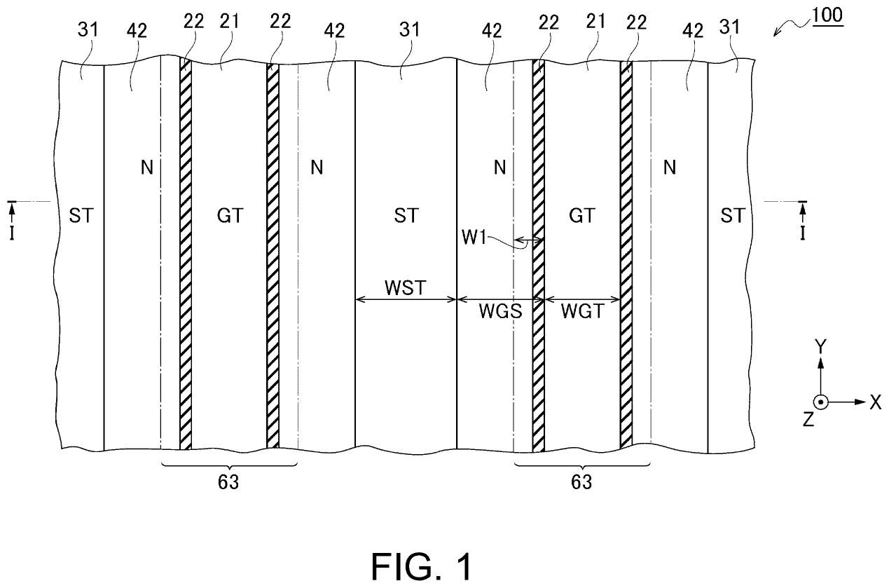

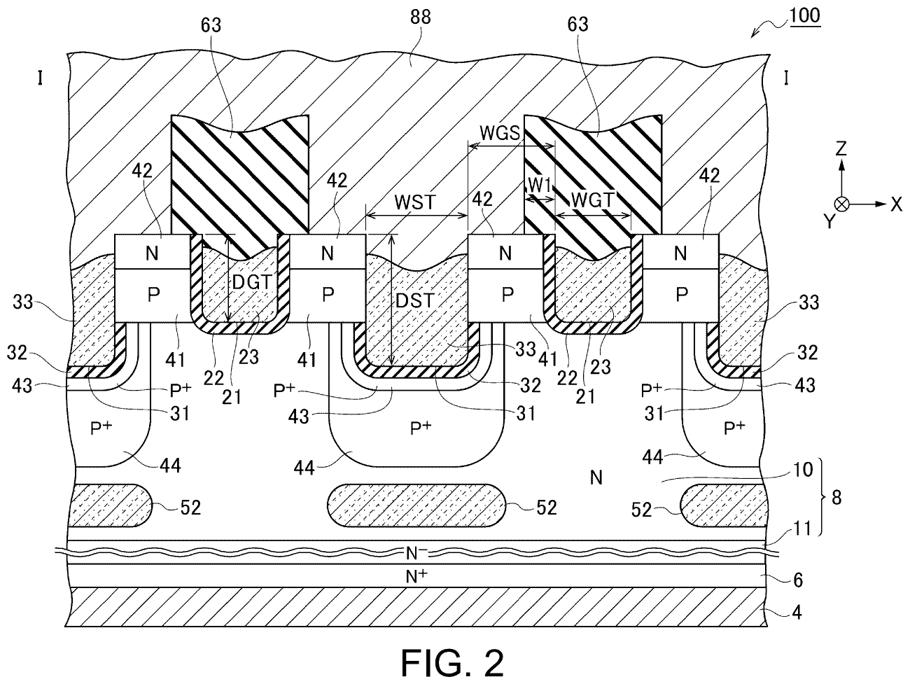

FIG. 1 is a top view of the overall structure of the semiconductor device 100 according to the first embodiment. FIG. 2 is a cross-sectional view (Structure example 1) taken along line I-I of FIG. 1.

As shown in FIG. 1, on the semiconductor substrate surface spreading on the XY plane, the gate trench (GT) 21 and the source trench (ST) 31 are provided extending parallel to each other. The gate trench (GT) 21 is arranged extending in the Y direction, and the source trench (ST) 31 extending in the Y direction is arranged in the plus-minus X direction, sandwiching the gate trench (GT) 21. In the plus-minus X direction of the gate trench (GT) 21, a gate insulating film 22 is provided. The width of the gate trench (GT) 21 in the X direction is defined by WGT, and the width of the source trench (ST) 31 in the X direction is defined by WST.

As shown in FIG. 1, in a plan view, on the semiconductor substrate surface between the gate trench (GT) 21 and the source trench (ST) 31, an n-type source region 42 is provided adjacent to the gate insulating film 22. The n-type source region 42 is provided adjacent to the source trench (ST) 31.

As shown in FIG. 2, in the semiconductor device 100 according to the first embodiment, on the semiconductor substrate surface between the gate trench (GT) 21 and the source trench (ST) 31, an n-type source region 42 is provided adjacent to the gate insulating film 22 and the source trench (ST) 31.

The semiconductor device 100 according to the first embodiment includes an n-type drift region 8 (10, 11), a p-type base region 41 on the n-type drift region 8 (10, 11), an n-type source region 42 on the p-type base region 41, a gate electrode 23 disposed on the p-type base region 41 via the gate insulating film 22, a source trench (ST) 31 provided on the p-type base region 41, and an n-type polysilicon electrode 33 electrically connected to the p-type base region 41 and the n-type source region 42, and provided in the source trench (ST) 31.

The n-type polysilicon electrode 33 is doped with phosphorus (P), and has an impurity concentration of 1×10¹⁷ cm⁻³ or more.

In the semiconductor device 100 according to the first embodiment, the p-type base region 41 and the n-type source region 42 are connected to the n-type polysilicon electrode 33 on the side surface of the source trench (ST) 31.

The semiconductor device 100 according to the first embodiment may further include a first p-type deep well region (first auxiliary region) 43 that is connected to the p-type base region 41, is on the side surface of the source trench (ST) 31 below the n-type source region 42, and has a higher impurity concentration than the p-type base region 41. The first p-type deep well region (first auxiliary region) 43 is formed deeper than the gate trench (GT) 21. The first p-type deep well region (first auxiliary region) 43 may be connected to the n-type polysilicon electrode 33.

The semiconductor device 100 according to the first embodiment further has an upper portion metal electrode 88 including metal, which is connected to the upper surface of the n-type source region 42, extends into the source trench (ST) 31, and is also connected to the n-type polysilicon electrode 33. The upper surface of the n-type polysilicon electrode 33 is at a position lower than the upper surface of the n-type source region 42, and the upper portion metal electrode 88 is also connected to the n-type polysilicon electrode 33 on the side surface of the source trench (ST) 31. Then, it is desirable that the upper surface of the n-type polysilicon electrode 33 is higher than the upper surface of the p-type base region 41 on the side surface side of the source trench (ST) 31.

In the semiconductor device 100 according to the first embodiment, the n-type drift region 8 (10, 11), the p-type base region 41, and the n-type source region 42 are composed of silicon carbide.

In the semiconductor device 100 according to the first embodiment, a p-type third auxiliary region 44 connected to the n-type polysilicon electrode 33 is further provided between the bottom portion of the source trench (ST) 31 and the n-type drift region 11. Here, the thickness of the third auxiliary region 44 may be set to be thicker than the thickness of the p-type base region 41.

In the semiconductor device 100 according to the first embodiment, between the bottom portion and side surface of the source trench (ST) 31 and the n-type drift region 10, a p-type third auxiliary region 44 connected to the n-type polysilicon electrode 33 is further provided, and the maximum impurity concentration of the third auxiliary region 44 is set higher than the maximum impurity concentration of the p-type base region 41.

### (Aspect Ratio of the Source Trench)

In the semiconductor device 100 according to the first embodiment, the semiconductor device 100 further includes a gate trench (GT) 21 that penetrates the p-type base region 41 and reaches the n-type drift region 10, and the gate electrode 23 is disposed within the gate trench (GT) 21. The depth DST of the source trench (ST) 31 may be a depth equal to or greater than the depth DGT of the gate trench (GT) 21.

### (Manufacturing Method)

In the semiconductor device 100 according to the first embodiment, a step of providing the polysilicon in the source trench (ST) 31 and a step of providing the polysilicon in the gate trench (GT) 21 may be performed simultaneously, and a step of introducing impurities into the polysilicon in the source trench (ST) 31 and a step of introducing impurities into the polysilicon in the gate trench (GT) 21 may be performed simultaneously.

In the semiconductor device 100 according to the first embodiment, as shown in FIG. 1 and FIG. 2, the n-type drift region 8 may be a stacked structure in which an n-type drift region 10 of a relatively high concentration is provided on an n-type drift region 11 of a relatively low concentration. The n-type drift region 10 is locally formed only in a region directly under the gate trench (GT) 21, and may be spaced apart from the source trench (ST) 31, the first p-type deep well region 43, and the second p-type deep well region 44. Thus, in the semiconductor device 100 according to the first embodiment, although the depletion layer due to the n-type drift region 10 of a relatively high concentration does not easily spread, the depletion layer easily spreads from the interface between the source trench (ST) 31, the first p-type deep well region 43, and the second p-type deep well region 44, and the n-type drift region 10, toward the n-type drift region 10 of a relatively high concentration.

In the semiconductor device 100 according to the first embodiment, as shown in FIG. 1 and FIG. 2, a gate trench (GT) 21 is provided on (on the side surface of) the p-type base region 41 extending from the n-type source region 42 to the n-type drift region 10, and within the gate trench (GT) 21, via the gate insulating film 22, a gate electrode 23 is provided, in which n-type polysilicon doped with phosphorus impurities of 1×10¹⁷ cm⁻³ or more, more preferably 1×10¹⁸ cm⁻³ or more, even more preferably 1×10¹⁹ cm⁻³ or more, or metal is embedded.

In the semiconductor device 100 according to the first embodiment, it may be a planar gate structure in which the gate trench (GT) 21 is not present, and the gate electrode 23 is formed on the upper surface of the p-type base region 41 via the gate insulating film 22. Further, when the gate electrode 23 made of p-type polysilicon is of a normally-off type, a buried channel structure is formed, and thus it is difficult to shorten the channel length due to the short channel effect, and it is difficult to improve the channel conductance. When the gate electrode 23 made of n-type polysilicon is of a normally-off type, it has a surface channel structure, so that the short channel effect is unlikely to occur and it is possible to improve the channel conductance.

In the semiconductor device 100 according to the first embodiment, as shown in FIG. 1 and FIG. 2, an upper portion metal electrode 88 including metal is provided on the gate electrode 23 via the interlayer insulating film 63. The upper portion metal electrode 88 is in contact with the n-type source region 42 on the upper surface of the substrate, and the interface may be silicided or have an alloy layer formed thereon to provide ohmic contact (low resistance contact). Further, the upper portion metal electrode 88 is connected with the auxiliary electrode 33 made of n-type polysilicon on the upper surface of the substrate. Further, on the back surface side of the substrate, an N⁺ drain region 6 is formed in contact with the n-type drift region 11, and a back surface electrode (drain electrode) 4 is connected to the N⁺ drain region 6.

In the semiconductor device 100 according to the first embodiment, as shown in FIG. 1 and FIG. 2, a source trench (ST) 31 is provided, spaced apart from the gate trench (GT) 21 and reaching from the n-type source region 42 to the n-type drift region 10. Here, although the depth DST of the source trench (ST) 31 in the minus Z direction is formed to a depth equal to or greater than the depth DGT of the gate trench (GT) 21 in the minus Z direction, if the second p-type deep well region 44 is formed deeper than the depth DGT of the gate trench (GT) 21 in the minus Z direction, the depth DST of the source trench (ST) 31 in the minus Z direction may be shallower than the depth DGT of the gate trench (GT) 21 in the minus Z direction. The width WST of the source trench (ST) 31 in the X direction may be the same width as the width WGT of the gate trench (GT) 21 in the X direction. Further, the source trench (ST) 31 may have substantially the same width WST downward in the minus Z direction, or may become narrower.

In the semiconductor device 100 according to the first embodiment, as shown in FIG. 1 and FIG. 2, an n-type source region 42 is provided on the p-type base region 41, and this p-type base region 41 and n-type source region 42 are connected to the n-type polysilicon electrode (auxiliary electrode) 33 on the side surface of the source trench (ST) 31.

In the semiconductor device 100 according to the first embodiment, as shown in FIG. 1 and FIG. 2, the source insulating film 32 is not provided on the side surface of the source trench (ST) 31 above (in the Z direction) the depth of the p-type base region 41. Alternatively, the source insulating film 32 may not be provided on the side surface of the source trench (ST) 31 above the depth of the bottom portion of the gate trench (GT) 21. Further, the source insulating film 32 may not be provided over the entire bottom portion and side surface of the source trench (ST) 31.

In the semiconductor device 100 according to the first embodiment, the source insulating film 32 may be provided only at the bottom portion of the source trench (ST) 31. Thereby, occurrence of punch-through at the bottom portion of the source trench (ST) 31 where electric field concentration is likely to occur locally may be reduced. Furthermore, as shown in FIG. 2, in the n-type drift region 10 between the back surface electrode 4 and the bottom portion of the source trench (ST) 31, a fourth auxiliary region 52 at a floating potential may be provided, spaced apart from the source trench (ST) 31. By this fourth auxiliary region 52, the depletion layer in the vicinity of the bottom portion of the source trench where electric field concentration is likely to occur locally may be further spread, and the occurrence of punch-through may be further reduced. It is noted that, the fourth auxiliary region 52 may be formed by a semiconductor region doped to a lower concentration than the p-type or the surrounding n-type drift region 10.

In the semiconductor device 100 according to the first embodiment, as shown in FIG. 1 and FIG. 2, the interlayer insulating film 63 is not provided around the periphery of the opening portion of the source trench (ST) 31, and the width W1 in the X direction from the opening portion of the gate trench (GT) 21 to the end of the interlayer insulating film 63 is narrower than the gate trench (GT) 21-source trench (ST) 31 interval WGS. Thus, the upper surface of the n-type source region 42 is connected to the upper portion metal electrode 88.

In the semiconductor device 100 according to the first embodiment, as shown in FIG. 1 and FIG. 2, the upper surface of the polysilicon in the source trench (ST) 31 is below the trench opening portion of width WST, and the upper portion metal electrode 88 also extends into the source trench (ST) 31. Then, the interlayer insulating film 63 is not formed on the upper surface of the substrate around the periphery of the opening portion of the source trench (ST) 31. Thereby, the upper portion metal electrode 88 is provided with a two-step structure. As a result, due to an anchor effect, the adhesion of the upper portion metal electrode 88 is improved, and peeling and the like in a wire bonding process with the upper portion metal electrode 88 or a connection process between the upper portion metal electrode 88 and a lead may be suppressed.

Inside the source trench (ST) 31, an auxiliary electrode 33 is provided, in which n-type polysilicon, doped with phosphorus (P) as an impurity, similar to the gate electrode 23, to an impurity concentration of 1×10¹⁸ cm⁻³ or more, and more preferably 1×10¹⁹ cm⁻³ or more, is embedded. The auxiliary electrode 33 in the source trench (ST) 31 has its upper portion connected to the upper portion metal electrode 88, and its side surface of the upper portion side is in contact with the side surface of the n-type source region 42 and the side surface of the p-type base region 41 (or the first p-type deep well region 43).

The first p-type deep well region 43 prevents the auxiliary electrode 33 in the source trench (ST) 31 from contacting the n-type drift region 10. In the case where the source insulating film 32 is provided in a local region of the source trench (ST) 31, the first p-type deep well region 43 may not be provided. Thus, the first p-type deep well region 43 is connected to the p-type base region 41, but it may be separated from the p-type base region 41.

A second p-type deep well region 44 is provided so as to include a corner portion of the bottom portion of the source trench (ST) 31. The second p-type deep well region 44 has a width in the X direction wider than that of the first p-type deep well region 43, and its maximum impurity concentration is higher than the maximum impurity concentration of the first p-type deep well region 43. It is noted that the maximum impurity concentration of the second p-type deep well region 44 may be lower than the maximum impurity concentration of the first p-type deep well region 43. Further, the second p-type deep well region 44 may be connected to the first p-type deep well region 43. It is noted that, in FIG. 2, the second p-type deep well region 44 is connected to the p-type base region 41, but it may be formed only on the bottom portion side of the source trench (ST) 31, separated from the p-type base region 41. Further, the first p-type deep well region 43 may not be provided, and the first p-type deep well region 43 may be formed on the bottom portion side of the source trench (ST) 31. It is noted that, in this case, the source insulating film 32 is not provided on the bottom portion side of the source trench (ST) 31, and the first p-type deep well region 43 and the auxiliary electrode 33 in the source trench (ST) 31 may be connected.

In the semiconductor device 100 according to the first embodiment, as shown in FIG. 1 and FIG. 2, an n-type source region 42 is formed extending from the gate trench (GT) 21 to the source trench (ST) 31. Then, on a portion of a side surface and an upper surface of the n-type source region 42, contact between the auxiliary electrode 33 and the upper portion metal electrode 88 is ensured. Thus, a wide source contact between the auxiliary electrode 33 and the upper portion metal electrode 88 is ensured, and on-resistance may be reduced. Further, due to the auxiliary electrode 33 being connected to the first p-type deep well region 43 and second p-type deep well region 44, during an off-state of the transistor (semiconductor device 100), in response to holes in the vicinity of the source trench (ST) 31 being extracted to the auxiliary electrode 33, the number of holes extracted into the auxiliary electrode 33 without moving in the vicinity of an interface between the n-type source region 42 and the p-type base region 41 increases, so holes moving within the p-type base region 41 directly under the n-type source region 42 decrease, the occurrence of parasitic transistor operation is reduced, and the occurrence of secondary breakdown may be reduced. For this reason, it is desirable that the auxiliary electrode 33 is in direct contact with the first p-type deep well region 43 and the second p-type deep well region 44.

### Second Embodiment: Structure Example 2

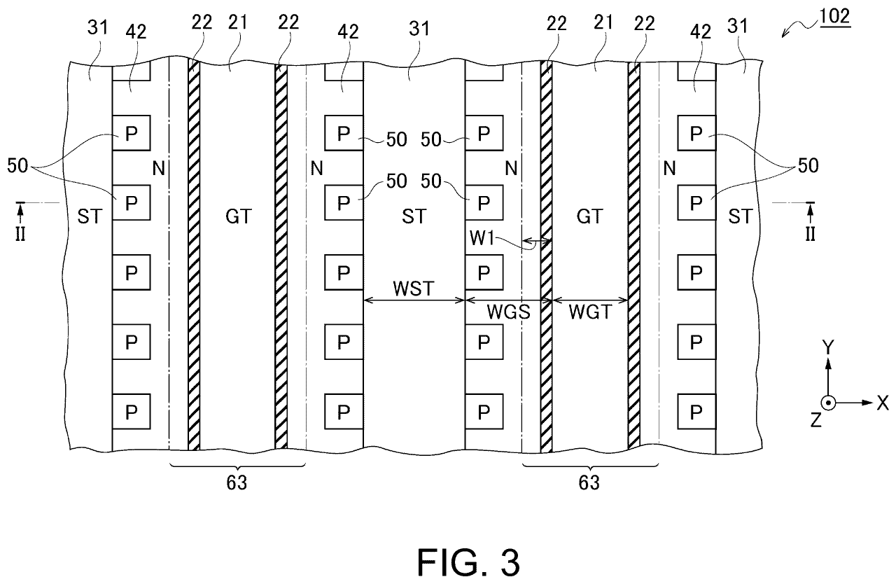

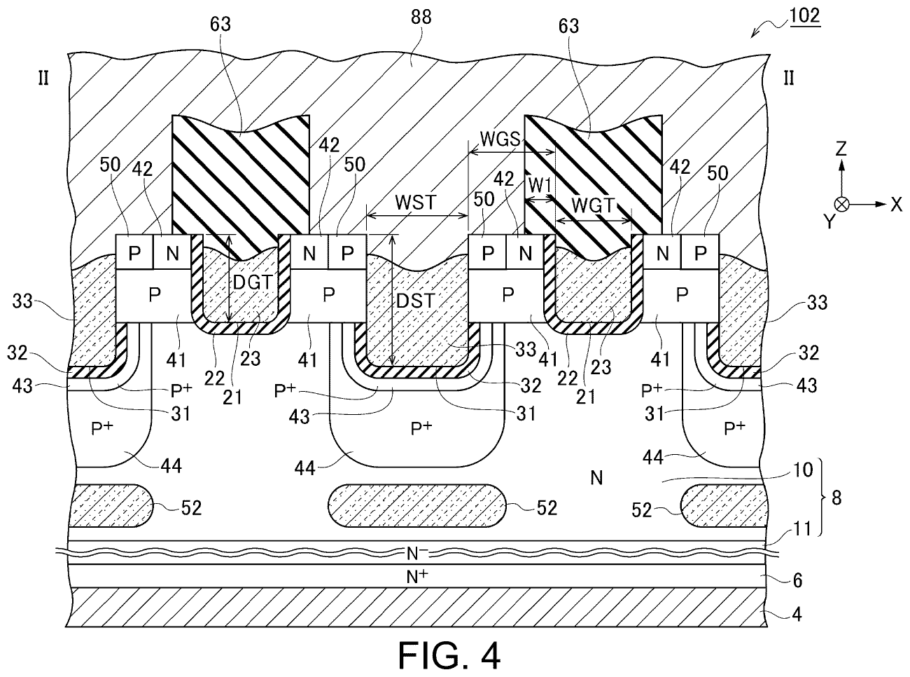

FIG. 3 is a top view of an overall structure of a semiconductor device 102 according to the second embodiment. FIG. 4 is a cross-sectional view (Structure example 2) along line II-II of FIG. 3. Hereinafter, points different from the first embodiment will be described, and redundant description will be omitted.

In the semiconductor device 102 according to the second embodiment, as shown in FIG. 3 and FIG. 4, on a semiconductor substrate surface between the gate trench (GT) 21 and the source trench (ST) 31, an n-type source region 42 is provided adjacent to the gate trench (GT) 21, and a p-region (second auxiliary region) 50 is provided adjacent to the source trench (ST) 31. The p-region 50 is provided at predetermined intervals in the Y direction. It is noted that p-regions 50 adjacent in the Y direction may be connected to each other, and the p-region 50 may be provided extending in the Y direction. Further, the p-region 50 may be extended in the X direction so as to be adjacent to the gate insulating film 22 on a side surface of the gate trench (GT) 21.

The semiconductor device 102 according to the second embodiment, as shown in FIG. 3 and FIG. 4, in a plan view, in the longitudinal direction (Y direction) of the trench, may be considered as a configuration in which Structure example 1 (FIG. 2) of the semiconductor device 100 according to the first embodiment and Structure example 2 (FIG. 4) including the p-region 50 on the surface of the substrate are alternately combined in the Y direction. That is, in the semiconductor device 102 according to the second embodiment, a region where multiple Structure examples 1 (FIG. 2) are arranged side by side and a region where multiple Structure examples 2 (FIG. 4) are arranged side by side are alternately provided.

In the semiconductor device 102 according to the second embodiment, on the p-type base region 41 between the n-type source region 42 and the source trench (ST) 31, a p-type second auxiliary region 50 having an impurity concentration higher than that of the p-type base region 41 is provided, and the second auxiliary region 50 is connected to the n-type polysilicon electrode 33.

In the semiconductor device 102 according to the second embodiment, as shown in FIG. 3 and FIG. 4, an upper portion metal electrode 88 including metal is provided on the gate electrode 23 via the interlayer insulating film 63. The upper portion metal electrode 88 is in contact with the n-type source region 42 on the upper surface of the substrate and the p-region 50 on the surface of the substrate, and an interface thereof may be silicided or have an alloy layer formed thereon to provide ohmic contact (low resistance contact).

In the semiconductor device 102 according to the second embodiment, as shown in FIG. 3 and FIG. 4, the interlayer insulating film 63 is not provided in the periphery of the opening portion of the source trench (ST) 31, and the width W1 in the X direction from the opening portion of the gate trench (GT) 21 to an end of the interlayer insulating film 63 is narrower than a gate trench (GT) 21-source trench (ST) 31 interval WGS. Thus, upper surfaces of the n-type source region 42 and the p-region 50 are connected to the upper portion metal electrode 88. Further, a side surface of the p-region 50 on the surface of the substrate is also connected to the n-type polysilicon electrode 33.

In the semiconductor device 102 according to the second embodiment, as shown in FIG. 3 and FIG. 4, on the side wall of the source trench (ST) 31 that contacts the auxiliary electrode 33, the n-type source region 42, and the p-region 50, the source insulating film 32 is not provided. Further, the p-region 50 on the surface of the substrate is formed deeper than the n-type source region 42. Since the p-region 50 on the surface of the substrate is formed deeper than the n-type source region 42 in the minus Z direction, holes that have moved upward (in the plus Z direction) may easily move into the p-region 50 on the surface of the substrate before crossing the p-type base region 41 directly under the n-type source region 42. As a result, the number of holes crossing the p-type base region 41 directly under the n-type source region 42 is reduced, and the occurrence of parasitic transistor operation may be further reduced.

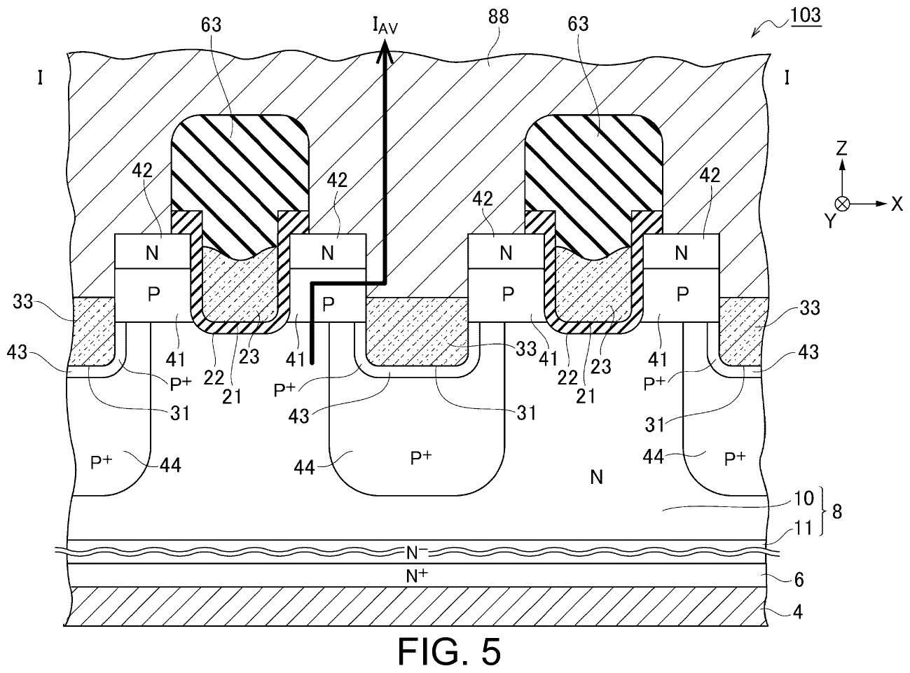

FIG. 5 is a cross-sectional view (Structure example 3) of the semiconductor device 103 according to the third embodiment, corresponding to the cross-section that follows line I-I in FIG. 1. A top view of the overall structure of the semiconductor device 103 is the same as that shown in FIG. 1.

The semiconductor device 103 according to the third embodiment is a modification example of the semiconductor device 100 according to the first embodiment.

As shown in FIG. 5, the n-type polysilicon electrode 33 is provided at the bottom portion of the source trench (ST) 31, and the upper portion metal electrode 88 connected to an upper surface of the n-type source region 42 extends into the source trench (ST) 31. That is, in the source trench (ST) 31, the n-type polysilicon electrode 33 is disposed closer to the bottom portion side than the upper portion metal electrode 88, and a depth of the upper portion metal electrode 88 on the side surface side of the source trench (ST) 31 is formed deeper than a lower surface of the n-type source region 42.

By providing the n-type polysilicon electrode 33, which is highly embeddable, in the source trench (ST) 31, voids in the upper portion metal electrode 88 within the source trench (ST) 31 may be reduced. Hereby, narrowing of a current path of the upper portion metal electrode 88 in the source trench (ST) 31 may be prevented, and an increase in resistance of the upper portion metal electrode 88 may be prevented.

Further, in at least one connection with the p-type base region 41, the first p-type deep well region 43, or the second p-type deep well region 44 provided on a wall surface of the source trench (ST) 31, a connection with the upper portion metal electrode 88 in the source trench (ST) 31 results in a lower resistance compared to a connection with the n-type polysilicon electrode 33. In the case of forming the source trench (ST) 31 from a bottom portion of the gate trench (GT) 21 to a depth deeper than a thickness of the p-type base region 41 below the n-type source region 42, within the source trench (ST) 31, the avalanche current (I_{AV}) may flow from any of the p-type base region 41, the first p-type deep well region 43, or the second p-type deep well region 44 to the upper portion metal electrode 88 in the source trench (ST) 31, such that at least a portion thereof does not pass through the n-type polysilicon electrode 33, or replaces a portion thereof. Here, a resistance from the first p-type deep well region 43 or the second p-type deep well region 44 on the bottom portion side of the source trench (ST) 31 to the upper portion metal electrode 88 may be made a relatively low resistance. As a result, a resistance value during flowing of the avalanche current is further reduced, and an endurance capability of the semiconductor device 103 may be secured. Furthermore, a depth of a contact surface on the side wall side of the source trench (ST) 31 between the n-type polysilicon electrode 33 and the upper portion metal electrode 88 may be formed to be approximately the same depth as a depth of a junction surface on the side wall side of the gate trench (GT) 21 between the p-type base region 41 and the n-type drift region 10, or may be formed deeper. In particular, it is desirable to form the source trench (ST) 31 from the bottom portion of the gate trench (GT) 21 to a depth deeper than a thickness of the p-type base region 41 below the n-type source region 42. Hereby, the resistance value during flowing of the avalanche current may be further reduced, and the endurance capability of the semiconductor device 103 may be further improved.

Also in the semiconductor device 103 according to a third embodiment, similarly to the semiconductor device 100 according to the first embodiment, the source insulating film 32 is not provided on a side surface of the source trench (ST) 31 on an upper side (Z direction) than a depth of the p-type base region 41. Alternatively, the source insulating film 32 may not be provided on the side surface of the source trench (ST) 31 above the depth of the bottom portion of the gate trench (GT) 21. Further, the source insulating film 32 may not be provided over the entire bottom portion and side surface of the source trench (ST) 31.

It is noted that in FIG. 5, although omitted in the figure, also in the third embodiment, the fourth auxiliary region 52 of floating potential may be provided in the n-type drift region 10 between the back surface electrode 4 and the bottom portion of the source trench (ST) 31, spaced apart from the source trench (ST) 31. By this fourth auxiliary region 52, the depletion layer in the vicinity of the bottom portion of the source trench where electric field concentration is likely to occur locally may be further spread, and the occurrence of punch-through may be further reduced. It is noted that, the fourth auxiliary region 52 may be formed by a semiconductor region doped to a lower concentration than the p-type or the surrounding n-type drift region 10.

### Fourth Embodiment: Structure Example 4

A structure similar to the semiconductor device 102 according to the third embodiment may be applied not only to the semiconductor device 100 of the first embodiment of FIG. 2 but also to the semiconductor device 102 of the second embodiment of FIG. 4.

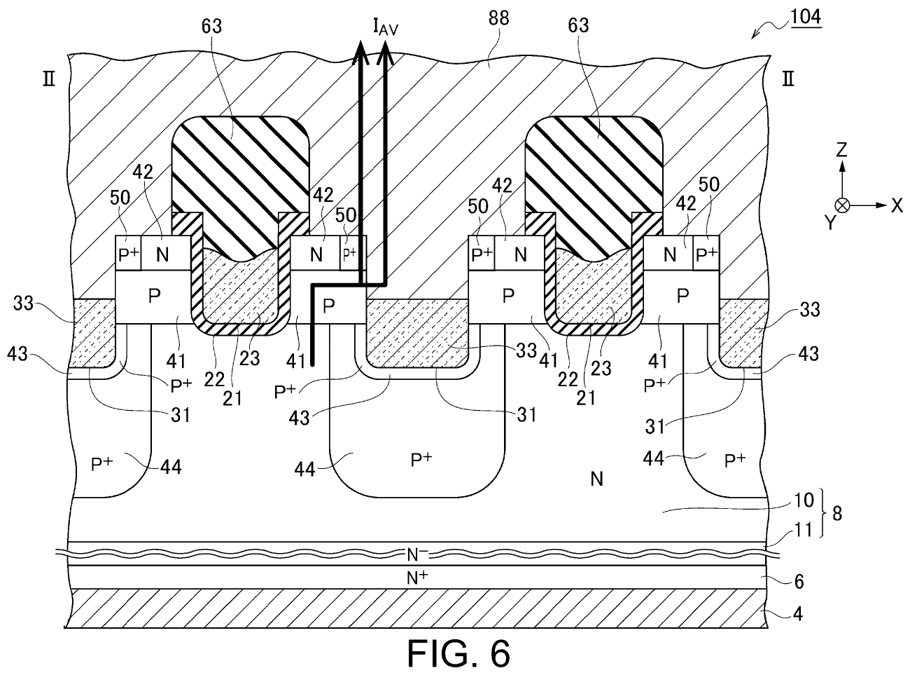

FIG. 6 is a cross-sectional view (Structure example 4) of the semiconductor device 104 according to the fourth embodiment, corresponding to the cross-section that follows line II-II in FIG. 3. A top view of the overall structure of the semiconductor device 104 is the same as that shown in FIG. 3.

The semiconductor device 104 according to the fourth embodiment is a modification example of the semiconductor device 102 according to the second embodiment. Hereinafter, points different from the second embodiment will be described, and redundant description will be omitted.

Also, in the semiconductor device 104 according to the fourth embodiment, as shown in FIG. 6, a depth of the upper portion metal electrode 88 on the side wall side of the source trench (ST) 31 is formed deeper than a lower surface of the n-type source region 42.

A source insulating film 32 (see FIG. 4) is not provided between the source trench (ST) 31 and the upper portion metal electrode 88 on the side wall side of the source trench (ST) 31, and the upper portion metal electrode 88 in the source trench (ST) 31 connects to the p-region (second auxiliary region) 50 on the side wall side of the source trench (ST) 31. Then, it connects to any one of the p-type base region 41, the first p-type deep well region 43, or the second p-type deep well region 44 below the p-region (second auxiliary region) 50. Thereby, an avalanche current (I_{AV}) may flow from any one of the p-type base region 41, the first p-type deep well region 43, or the second p-type deep well region 44 to the upper portion metal electrode 88 via the p-region 50. Further, an avalanche current (I_{AV}) may flow from any one of the p-type base region 41, the first p-type deep well region 43, or the second p-type deep well region 44 to the upper portion metal electrode 88 in the source trench (ST) 31, without passing through at least a portion of the n-type polysilicon electrode 33, or so as to replace a portion thereof. Further, voids in the upper portion metal electrode 88 in the source trench (ST) 31 may be reduced. As a result, the withstanding capability of the semiconductor device 104 is improved. Here, similar to the semiconductor device 103 according to the third embodiment, also in the fourth embodiment, the depth of the contact surface on the side wall side of the source trench (ST) 31 between the n-type polysilicon electrode 33 arranged at the bottom portion of the source trench (ST) 31 and the upper portion metal electrode 88 may be formed to be approximately the same depth as, or deeper than, the depth of the junction surface on the side wall side of the gate trench (GT) 21 between the p-type base region 41 and the n-type drift region 10. In particular, it is desirable to form the source trench (ST) 31 from the bottom portion of the gate trench (GT) 21 to a depth deeper than a thickness of the p-type base region 41 below the n-type source region 42. Thereby, the resistance value during the flow of the avalanche current (I_{AV}) may be further reduced, and the withstanding capability of the semiconductor device 103 may be further improved.

It is noted that in FIG. 6, although not illustrated, also in the fourth embodiment, a fourth auxiliary region 52 at a floating potential may be provided in the n-type drift region 10 between the back surface electrode 4 and the bottom portion of the source trench (ST) 31, spaced apart from the source trench (ST) 31. By this fourth auxiliary region 52, the depletion layer in the vicinity of the bottom portion of the source trench where electric field concentration is likely to occur locally may be further spread, and the occurrence of punch-through may be further reduced. It is noted that, the fourth auxiliary region 52 may be formed by a semiconductor region doped to a lower concentration than the p-type or the surrounding n-type drift region 10.

### OTHER EMBODIMENTS

Although some embodiments of the disclosure have been described, these embodiments are presented as examples, and are not intended to limit the scope of the disclosure. Novel embodiments may be implemented in various other forms, and various omissions, replacements, and changes may be made without departing from the gist of the disclosure. For example, constituent elements of one embodiment may be replaced with or changed to constituent elements of another embodiment. Furthermore, in the above-described embodiments, an example is shown in which the gate trench (GT) 21 and the source trench (ST) 31 extend in the plus-minus Y direction, however, in a top view, multiple source trenches (ST) 31 may be arranged in a dot pattern, and the gate trenches (GT) 21 may be arranged in a lattice pattern so as to surround each source trench (ST) 31. Furthermore, the upper portion metal electrode 88 may be formed by laminating multiple metals of different materials. These embodiments and modifications thereof are included in the scope and spirit of the invention, and are included within the scope of the invention described in the claims and equivalents thereof. Furthermore, an electronic machine including the semiconductor device described above may be provided. The electronic machine including the semiconductor device described above is, for example, an inverter that drives an electric motor used as a power source for electric vehicles (including hybrid vehicles), trains, industrial robots, etc., and also a power module for an inverter circuit that converts electric power generated by a power conditioner of a solar power generation system, a wind power generator, or other power generation devices (particularly private power generation devices) into electric power of a commercial power source, etc.

What is claimed is:

1. A semiconductor device, comprising: a drift region of a first conductivity type;
a base region of a second conductivity type on the drift region;
a source region of a first conductivity type on the base region;
a gate electrode disposed on the base region via an insulating film;
an auxiliary trench provided on the base region; and
a polysilicon electrode of a first conductivity type, electrically connected to the base region and the source region, and provided in the auxiliary trench.

2. The semiconductor device according to claim 1, wherein the polysilicon electrode is doped with phosphorus (P), and has an impurity concentration of 1×10¹⁷ cm⁻³ or more.

3. The semiconductor device according to claim 2, wherein the side surface of the source region is electrically connected to the polysilicon electrode at a side surface of the auxiliary trench.

4. The semiconductor device according to claim 3, further comprising a first auxiliary region of a second conductivity type, having a higher impurity concentration than the base region, connected to the base region, and connected to the polysilicon electrode at a side surface or a bottom surface of the auxiliary trench below the source region.

5. The semiconductor device according to claim 1, wherein a third auxiliary region of a second conductivity type is further provided between a bottom portion of the auxiliary trench and the drift region, and
a thickness of the third auxiliary region is set to be thicker than a thickness of the base region.

6. The semiconductor device according to claim 1, wherein a third auxiliary region of a second conductivity type, connected to the polysilicon electrode, is further provided between a bottom portion and a side surface of the auxiliary trench and the drift region, and
a maximum impurity concentration of the third auxiliary region is set to be higher than a maximum impurity concentration of the base region.

7. The semiconductor device according to claim 2, wherein a second auxiliary region of a second conductivity type, having a higher impurity concentration than the base region, is further provided on the base region between the source region and the auxiliary trench, and
the second auxiliary region is connected to the polysilicon electrode.

8. The semiconductor device according to claim 1, further comprising an electrode including metal, connected to an upper surface of the source region, extending into the auxiliary trench, and also connected to the polysilicon electrode.

9. The semiconductor device according to claim 8, wherein the base region and the source region are formed of silicon carbide.

10. The semiconductor device according to claim 1, further comprising a gate trench extending through the base region and reaching the drift region,
wherein the gate electrode is disposed in the gate trench, and
a depth of the auxiliary trench is set to be greater than or equal to a depth of the gate trench.

11. The semiconductor device according to claim 1, further comprising: an electrode including a metal, connected to an upper surface of the source region, extending into the auxiliary trench, and also connected to the polysilicon electrode,
wherein the electrode including the metal on a side surface side of the auxiliary trench extends to below a lower surface of the source region, and
the polysilicon electrode is provided further towards a bottom portion side of the auxiliary trench than the electrode including the metal.

12. The semiconductor device according to claim 11, wherein an insulating film is not provided between the auxiliary trench and the electrode including the metal in the auxiliary trench.

13. The semiconductor device according to claim 12, wherein the base region is electrically connected to the electrode including the metal below a lower surface of the source region.

14. A manufacturing method of a semiconductor device, the semiconductor device comprising: a drift region of a first conductivity type;
a base region of a second conductivity type on the drift region;
a source region of a first conductivity type on the base region;
a gate electrode provided in a gate trench, the gate trench being disposed on the base region via an insulating film;
an auxiliary trench provided on the base region; and
a polysilicon electrode of a first conductivity type, electrically connected to the base region and the source region, and provided in the auxiliary trench, and
the manufacturing method of the semiconductor device comprising:
simultaneously performing a step of providing a polysilicon in the auxiliary trench and a step of providing a polysilicon in the gate trench; and
simultaneously performing a step of introducing an impurity into a polysilicon in the auxiliary trench and a step of introducing an impurity into a polysilicon in the gate trench.

15. An electronic machine, comprising the semiconductor device according to claim 1.
